(19) United States
(12) Patent Application Publication
(10) Pub. No.: US 2023/0090522 A1
(43) Pub. Date: Mar. 23, 2023

(54) LIGHT-EMITTING DEVICE, PROJECTOR, AND DISPLAY

(71) Applicants: SEIKO EPSON CORPORATION, Tokyo (JP); SOPHIA SCHOOL CORPORATION, Tokyo (JP)

(72) Inventors: Hiroaki JIROKU, SUWA SHI (JP); Takafumi NODA, MATSUMOTO-SHI (JP); Katsumi KISHINO, AKIRUNO-SHI (JP)

(73) Assignees: SEIKO EPSON CORPORATION, Tokyo (JP); SOPHIA SCHOOL CORPORATION, Tokyo (JP)

(21) Appl. No.: 17/943,181

(22) Filed: Sep. 12, 2022

(30) Foreign Application Priority Data
Sep. 13, 2021 (JP) 2021-148472

(51) Int. Cl. H01S 5/042

(52) U.S. Cl. CPC H01S 5/04253; H04N 9/3161

(57) ABSTRACT

A light-emitting device includes: a substrate; first column portions provided at the substrate; a plurality of second column portions provided at the substrate and that surround the first column portions as viewed from a normal direction of the substrate; a first semiconductor layer coupled to the first column portions; an insulating layer covering the first semiconductor layer and the second column portions; and a wiring line electrically coupled to the first semiconductor layer. Each of the first column portions and each of the second column portions includes an n-type second semiconductor layer, a p-type third semiconductor layer, and a u-type fourth semiconductor layer. The fourth semiconductor layer at each of the first column portions is injected with current to emit light. The fourth semiconductor layer at each of the second column portions is not injected with current. The wiring line overlaps at least one of the second column portions.

The present application is based on, and claims priority from JP Application Serial Number 2021-148472, filed Sep. 13, 2021, the disclosure of which is hereby incorporated by reference herein in its entirety.

### BACKGROUND

### 1. Technical Field

The present disclosure relates to a light-emitting device, a projector, and a display.

### 2. Related Art

Semiconductor lasers are expected as next-generation light sources having high luminance. In particular, semiconductor lasers to which nanocolumns are applied are expected to realize high-power light emission with a narrow radiation angle thanks to the photonic crystal effect of nanocolumns.

For example, JP-A-2013-502715 describes a method of manufacturing a light-emitting device including growing nanowires, forming a capsule layer so as to cover the free ends of the nanowires, forming a second electrode on the capsule layer, masking the second electrode, and etching the non-masked second electrode, capsule layer, and nanowires to individualize basic light-emitting regions.

In such a light-emitting device as described above, when the wiring line coupled to the second electrode is routed, an insulating layer covering the basic light-emitting regions is formed to prevent the wiring line and any of the nanowires in the basic light-emitting regions from coming into contact with each other. However, in JP-A-2013-502715, there are portions from which nanowires are removed between adjacent basic light-emitting regions, and thus a level difference is formed between such portions and the basic light-emitting regions. When a level difference is formed, the insulating layer does not adhere well, causing a leak current to flow between the wiring line and any of the nanowires of the basic light-emitting regions.

### SUMMARY

One aspect of a light-emitting device according to the present disclosure includes: a substrate, a plurality of first column portions provided at the substrate, a plurality of second column portions provided at the substrate and surrounding the plurality of first column portions when viewed from a normal direction of the substrate, a first semiconductor layer provided on an opposite side of the plurality of first column portions from the substrate and coupled to the plurality of first column portions, an insulating layer covering the first semiconductor layer and the plurality of second column portions, and a wiring line provided on an opposite side of the insulating layer from the substrate and electrically coupled to the first semiconductor layer, wherein each of the plurality of first column portions and each of the plurality of second column portions includes an n-type second semiconductor layer, a p-type third semiconductor layer, and a u-type fourth semiconductor layer provided between the second semiconductor layer and the third semiconductor layer, the fourth semiconductor layer at each of the plurality of first column portions is injected with current to emit light, the fourth semiconductor layer at each of the plurality of second column portions is not injected with current, and the wiring line overlaps at least one of the plurality of second column portions when viewed from the normal direction.

One aspect of a projector according to the present disclosure includes one aspect of the light-emitting device.

One aspect of a display according to the present disclosure includes one aspect of the light-emitting device.

### BRIEF DESCRIPTION OF THE DRAWINGS

FIG. 1 is a plan view schematically illustrating a light-emitting device according to a first embodiment.

FIG. 2 is a cross-sectional view schematically illustrating the light-emitting device according to the first embodiment.

FIG. 3 is a cross-sectional view schematically illustrating the light-emitting device according to the first embodiment.

FIG. 4 is a cross-sectional view schematically illustrating the light-emitting device according to the first embodiment.

FIG. 5 is a cross-sectional view schematically illustrating a manufacturing step for the light-emitting device according to the first embodiment.

FIG. 6 is a cross-sectional view schematically illustrating a manufacturing step for the light-emitting device according to the first embodiment.

FIG. 7 is a plan view schematically illustrating a light-emitting device according to a first reference example.

FIG. 8 is a cross-sectional view schematically illustrating the light-emitting device according to the first reference example.

FIG. 9 is a plan view schematically illustrating a light-emitting device according to a second embodiment.

FIG. 10 is a cross-sectional view schematically illustrating the light-emitting device according to the second embodiment.

FIG. 11 is a cross-sectional view schematically illustrating the light-emitting device according to the second embodiment.

FIG. 12 is a cross-sectional view schematically illustrating a light-emitting device according to a second reference example.

FIG. 13 is a plan view schematically illustrating a light-emitting device according to a third embodiment.

FIG. 14 is a cross-sectional view schematically illustrating the light-emitting device according to the third embodiment.

FIG. 15 is a view schematically illustrating a projector according to a fourth embodiment.

FIG. 16 is a plan view schematically illustrating a display according to a fifth embodiment.

FIG. 17 is a cross-sectional view schematically illustrating the display according to the fifth embodiment.

### DESCRIPTION OF EXEMPLARY EMBODIMENTS

Hereinafter, preferred embodiments of the present disclosure will be described in detail using the appended drawings. Note that the embodiments described below are not intended to unduly limit the content of the present disclosure as set forth in the claims. Furthermore, not all of the configurations described below necessarily represent essential requirements of the present disclosure.

### 1. First Embodiment

### 1.1. Light-Emitting Device

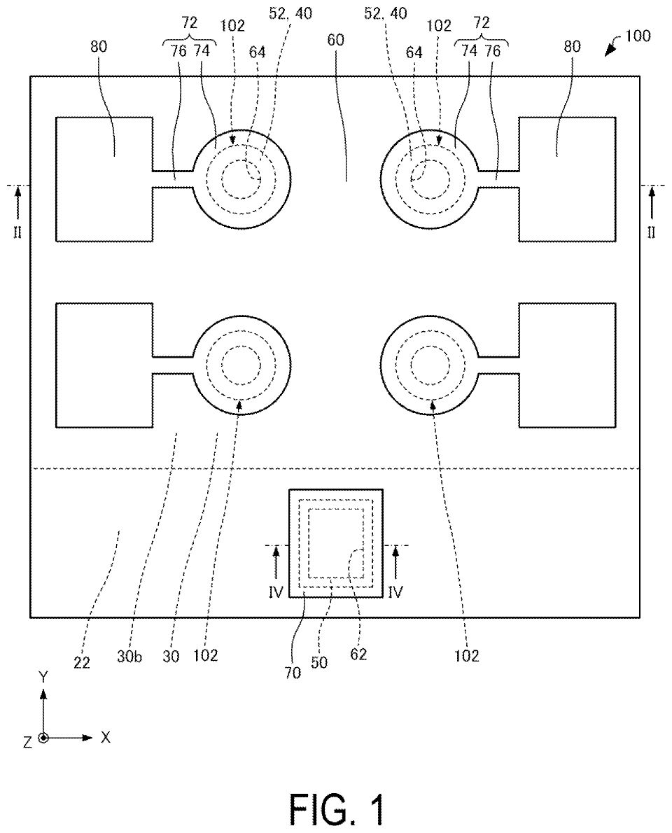

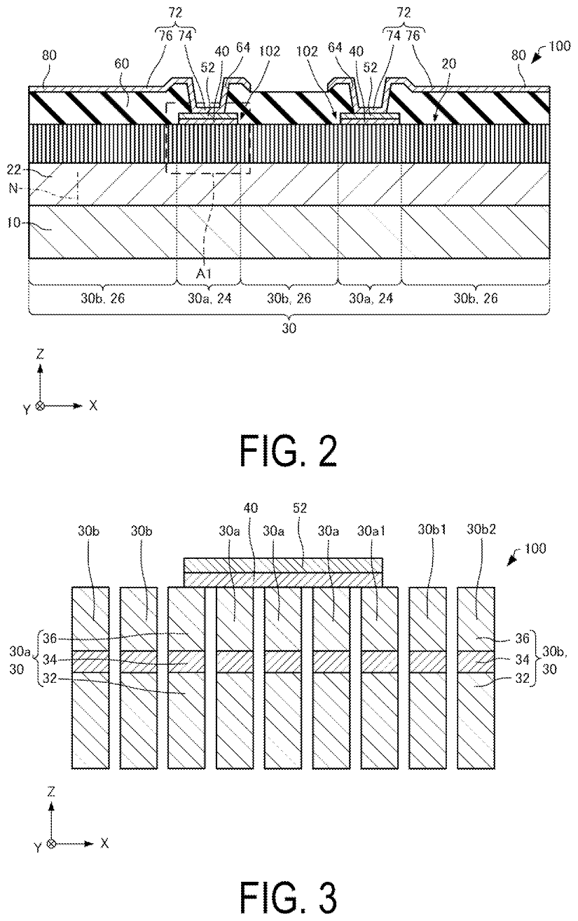

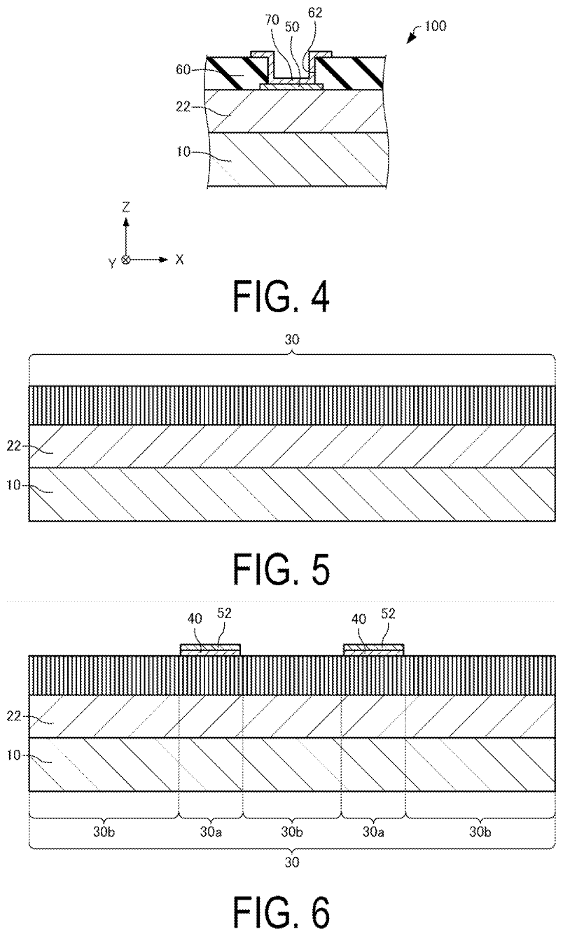

First, a light-emitting device according to a first embodiment will be described with reference to drawings. FIG. 1 is a plan view schematically illustrating a light-emitting device 100 according to the first embodiment. FIG. 2 is a cross-sectional view taken along the line II-II in FIG. 1 that schematically illustrate the light-emitting device 100 according to the first embodiment. FIG. 3 is a cross-sectional view schematically illustrating the light-emitting device 100 according to the first embodiment, and is an enlarged view of the region A1 in FIG. 2. FIG. 4 is a cross-sectional view taken along the line IV-IV in FIG. 1 that schematically illustrate the light-emitting device 100 according to the first embodiment. Note that in FIGS. 1 to 4, the X-axis, the Y-axis, and the Z-axis are illustrated as three axes orthogonal to one another.

As illustrated in FIGS. 1 to 4, the light-emitting device 100 includes, for example, a substrate 10, a laminate 20, a first semiconductor layer 40, a first electrode 50, second electrodes 52, an insulating layer 60, a first wiring line 70, a second wiring line 72, and pads 80.

The substrate 10 is, for example, an Si substrate, a GaN substrate, a sapphire substrate, an SiC substrate, or the like.

The laminate 20 is provided at the substrate 10. In the illustrated example, the laminate 20 is provided on the substrate 10. The laminate 20 includes, for example, a buffer layer 22 and a plurality of column portions 30. The column portions 30 each include an n-type second semiconductor layer (hereinafter also referred to as the “n-type semiconductor layer 32”), a p-type third semiconductor layer (hereinafter also referred to as the “p-type semiconductor layer 36”), and a u-type fourth semiconductor layer (hereinafter also referred to as the “u-type semiconductor layer 34”). Note that in FIG. 2, column portions 30 are illustrated in a simplified manner for convenience. Furthermore, in FIG. 3, members other than column portions 30, the first semiconductor layer 40, and a second electrode 52 are omitted from illustration.

In the present specification, when the u-type semiconductor layer 34 is used as reference in the stacking direction of the laminate 20 (hereinafter also simply referred to as the “stacking direction”), the direction going from the u-type semiconductor layer 34 toward the p-type semiconductor layer 36 is referred to as “upward”, and the direction going from the u-type semiconductor layer 34 toward the n-type semiconductor layer 32 is referred to as “downward”. Directions orthogonal to the stacking direction are also referred to as “in-plane directions”. Furthermore, the “stacking direction of the laminate 20” refers to the stacking direction of the n-type semiconductor layer 32 and the u-type semiconductor layer 34, and is the normal N direction of the substrate 10. In the illustrated example, the stacking direction is the Z-axis direction.

The buffer layer 22 is provided on the substrate 10. The buffer layer 22 is, for example, an n-type GaN layer doped with Si. Although not illustrated, a mask layer for growing the column portions 30 is provided on the buffer layer 22. The mask layer is, for example, a silicon oxide layer, a titanium layer, a titanium oxide layer, an aluminum oxide layer, or the like.

The column portions 30 are provided on the buffer layer 22. The column portions 30 each have a columnar shape protruding upward from the buffer layer 22. In other words, the column portions 30 protrude upward from the substrate 10 via the buffer layer 22. The column portions 30 are also referred to as, for example, nanocolumns, nanowires, nanorods, and nanopillars. The planar shape of the column portion 30 is, for example, a polygon such as a hexagon, or a circle.

The diameter of the column portion 30 is, for example, not less than 50 nm and not greater than 500 nm. Setting the diameter of the column portion 30 to not greater than 500 nm allows a high-quality crystalline u-type semiconductor layer 34 to be obtained, and the strain inherent in the u-type semiconductor layer 34 to be reduced. This makes it possible to amplify light generated by the u-type semiconductor layer 34 with high efficiency.

Note that when the planar shape of the column portion 30 is a circle, the “diameter of the column portion” is the diameter; and when the planar shape of the column portion 30 is not a circle, it is the diameter of the minimum inclusion circle. For example, when the planar shape of the column portion 30 is a polygon, the diameter of the column portion 30 is the diameter of the smallest circle including the polygon; and when the planar shape of the column portion 30 is an ellipse, it is the diameter of the smallest circle including the ellipse.

The column portions 30 are provided in plurality. The spacing between adjacent column portions 30 is, for example, not less than 1 nm and not greater than 500 nm. The plurality of column portions 30 are arranged in a predetermined pitch in a predetermined direction as viewed from the stacking direction. The plurality of column portions 30 are disposed in a triangular lattice shape or in a square lattice shape, for example. The plurality of column portions 30 can express the photonic crystal effect.

Note that the “pitch of column portions” is the distance between the centers of column portions 30 adjacent along the predetermined direction. When the planar shape of the column portion 30 is a circle, the “center of the column portion” is the center of such a circle; and when the planar shape of the column portion 30 is a shape other than a circle, it is the center of the minimum inclusion circle. For example, when the planar shape of the column portion 30 is a polygon, the center of the column portion 30 is the center of the smallest circle including the polygon; and when the planar shape of the column portion 30 is an ellipse, it is the center of the smallest circle including the ellipse.

The n-type semiconductor layer 32 of the column portions 30 is provided on the buffer layer 22. The n-type semiconductor layer 32 is provided between the substrate 10 and the u-type semiconductor layer 34. The n-type semiconductor layer 32 is, for example, an n-type GaN layer doped with Si.

The u-type semiconductor layer 34 of the column portions 30 is provided on the n-type semiconductor layer 32. The u-type semiconductor layer 34 is provided between the n-type semiconductor layer 32 and the p-type semiconductor layer 36. The u-type semiconductor layer 34 is an undoped semiconductor layer not intentionally doped with impurities. The u-type semiconductor layer 34 may be an i-type semiconductor layer formed of an intrinsic semiconductor. The u-type semiconductor layer 34 includes, for example, a well layer and a barrier layer. The well layer is, for example, an InGaN layer. The barrier layer is, for example, a GaN layer. The u-type semiconductor layer 34 has a multiple quantum well (MQW) structure constituted by the well layer and the barrier layer.

Note that the number of the well layer and the barrier layer that constitute the u-type semiconductor layer 34 is not particularly limited. For example, only one well layer may be provided, in which case the u-type semiconductor layer 34 has a single quantum well (SQW) structure.

The p-type semiconductor layer 36 of the column portions 30 is provided on the u-type semiconductor layer 34. The p-type semiconductor layer 36 is, for example, a p-type GaN layer doped with Mg.

Of the plurality of column portions 30, first column portions 30a are column portions that are injected with current to emit light. Of the plurality of column portions 30, second column portions 30b are column portions that are not injected with current. The first column portions 30a are provided in plurality. The second column portions 30b are provided in plurality. The plurality of first column portions 30a and the plurality of second column portions 30b are provided at the substrate 10. In the example illustrated in FIG. 2, the plurality of first column portions 30a and the plurality of second column portions 30b are provided at the substrate 10 via the buffer layer 22. The buffer layer 22 includes, for example, first regions 24 at which a plurality of first column portions 30a are provided, and a second region 26 at which a plurality of second column portions 30b are provided. The first regions 24 and the second region 26 are upper surfaces of the buffer layer 22 and are in contact with each other. The second region 26 surrounds the first regions 24 as viewed from the stacking direction. The plurality of second column portions 30b surround the plurality of first column portions 30a as viewed from the stacking direction.

In the example illustrated in FIG. 3, the plurality of second column portions 30b are provided continuous with the plurality of first column portions 30a. That is, the distance between a second column portion 30b1 and a first column portion 30a1 is the same as the distance between the second column portion 30b1 and a second column portion 30b2. The second column portion 30b1 is a column portion adjacent to the first column portion 30a1. Of the plurality of first column portions 30a, the first column portion 30a1 is a column portion that is located at the outermost position. The second column portion 30b2 is a column portion adjacent to the second column portion 30b1.

The diameter of the first column portion 30a and the diameter of the second column portion 30b are, for example, the same. The pitch of the plurality of first column portions 30a and the pitch of the plurality of second column portions 30b are, for example, the same. The height of the first column portions 30a and the height of the second column portions 30b are, for example, the same. Note that the “height of the column portions” refers to the size in the stacking direction of the column portions 30.

Each of the plurality of first column portions 30a and each of the plurality of second column portions 30b includes an n-type semiconductor layer 32, a u-type semiconductor layer 34, and a p-type semiconductor layer 36.

The u-type semiconductor layer 34 in each of the plurality of first column portions 30a is injected with current by the first electrode 50 and the second electrode 52 to emit light. The u-type semiconductor layer 34 of the first column portions 30a is a light-emitting layer that generates light.

The u-type semiconductor layer 34 in each of the plurality of second column portions 30b is not injected with current. Accordingly, the u-type semiconductor layer 34 of the second column portions 30b does not emit light. In the example illustrated in FIG. 3, the p-type semiconductor layer 36 of the second column portions 30b is electrically separated from the second electrode 52.

In the light-emitting device 100, a PIN diode is constituted by the p-type semiconductor layer 36 of a first column portion 30a, the u-type semiconductor layer 34 of the first column portion 30a, and the n-type semiconductor layer 32 of the first column portion 30a. In the light-emitting device 100, applying a forward bias voltage of the PIN diode between the first electrode 50 and the second electrode 52 causes the u-type semiconductor layer 34 of the first column portion 30a to be injected with current, causing a recombination of electrons and holes at the u-type semiconductor layer 34 of the first column portion 30a. This recombination generates light. The light generated at the u-type semiconductor layer 34 of the first column portion 30a propagates in in-plane directions, forms a standing wave due to the photonic crystal effect of the plurality of first column portions 30a, and receives the gain at the u-type semiconductor layer 34 of the first column portion 30a to lase. Then, the light-emitting device 100 emits +1 order diffracted light and −1 order diffracted light as laser light in the stacking direction.

Although not illustrated, a reflection layer may be provided between the substrate 10 and the buffer layer 22, or under or below the substrate 10. The reflection layer is, for example, a distributed Bragg reflector (DBR) layer. The reflection layer can reflect light generated at the u-type semiconductor layer 34 of the first column portion 30a, and the light-emitting device 100 can emit light only from the second electrode 52 side.

The first semiconductor layer 40 is provided on the opposite side of the plurality of first column portions 30a from the substrate 10 side. The first semiconductor layer 40 is provided on the plurality of first column portions 30a. The first semiconductor layer 40 is provided between the plurality of first column portions 30a and the second electrode 52. The first semiconductor layer 40 is coupled to the plurality of first column portions 30a. The thickness of the first semiconductor layer 40 is several tens of nm, for example. The first semiconductor layer 40 has the same conductivity type as that of the semiconductor layer of the first column portions 30a with which the first semiconductor layer 40 is in contact. In the illustrated example, the first semiconductor layer 40 is in contact with the p-type semiconductor layer 36 of the first column portions 30a. The first semiconductor layer 40 is, for example, a p-type GaN layer doped with Mg. In the example illustrated in FIG. 1, the planar shape of the first semiconductor layer 40 is circular.

As illustrated in FIG. 4, the first electrode 50 is provided on the buffer layer 22. The buffer layer 22 may be in ohmic contact with the first electrode 50. The first electrode 50 is electrically coupled to the n-type semiconductor layer 32 of the first column portions 30a. In the illustrated example, the first electrode 50 is electrically coupled to the n-type semiconductor layer 32 of the first column portions 30a via the buffer layer 22. The first electrode 50 is one electrode for injecting current into the u-type semiconductor layer 34 of the first column portions 30a. For the first electrode 50, for example, such as one in which a Cr layer, an Ni layer, and an Au layer are stacked in this order from the buffer layer 22 side is used.

As illustrated in FIGS. 2 and 3, the second electrodes 52 are provided on the opposite side of the first semiconductor layer 40 from the substrate 10. The second electrodes 52 are provided on the first semiconductor layer 40. The second electrodes 52 are provided between the first semiconductor layer 40 and the second wiring line 72. The first semiconductor layer 40 may be in ohmic contact with the second electrodes 52.

As illustrated in FIG. 1, the second electrodes 52 completely overlap the first semiconductor layer 40 as viewed from the stacking direction. That is, as viewed from the stacking direction, the second electrodes 52 do not include any portion that does not overlap the first semiconductor layer 40, and the first semiconductor layer 40 does not include any portion that does not overlap the second electrodes 52. In the illustrated example, the planar shape of the second electrodes 52 is circular. The second electrodes 52 are electrically coupled to the p-type semiconductor layer 36 of the first column portions 30a. In the illustrated example, the second electrodes 52 are electrically coupled to the p-type semiconductor layer 36 of the first column portions 30a via the first semiconductor layer 40. The second electrodes 52 are the other electrodes for injecting current into the u-type semiconductor layer 34 of the first column portions 30a. For the second electrodes 52, for example, indium tin oxide (ITO) or ZnO is used.

The second electrode 52, the first electrode 50, the first semiconductor layer 40, the plurality of first column portions 30a, and the buffer layer 22 constitute, for example, a light-emitting element 102. The light-emitting element 102 is a semiconductor laser. The light-emitting elements 102 are provided in plurality, for example. In the example illustrated in FIG. 1, four light-emitting elements 102 are provided. However, the number of the light-emitting element 102 is not particularly limited. The plurality of light-emitting elements 102 are arranged in a matrix in the X-axis direction and the Y-axis direction, for example. The buffer layer 22 is a layer common to the plurality of light-emitting elements 102. The first electrode 50 is an electrode common to the plurality of light-emitting elements 102. A plurality of second column portions 30b are provided between adjacent light-emitting elements 102. The plurality of second column portions 30b surround the light-emitting element 102 as viewed from the stacking direction.

As illustrated in FIG. 2, the insulating layer 60 covers the first semiconductor layer 40 and the plurality of second column portions 30b. In the illustrated example, the insulating layer 60 covers the first semiconductor layer 40 via the second electrodes 52. The insulating layer 60 is provided on the plurality of second column portions 30b, on the first electrode 50, and on the second electrodes 52. The insulating layer 60 is, for example, a silicon oxide layer or a silicon nitride layer.

As illustrated in FIG. 4, the insulating layer 60 is provided with a first contact hole 62. The first contact hole 62 overlaps the first electrode 50 as viewed from the stacking direction. As illustrated in FIG. 2, the insulating layer 60 is provided with second contact holes 64. The second contact holes 64 overlap the second electrodes 52 as viewed from the stacking direction.

As illustrated in FIG. 4, the first wiring line 70 is provided on the first electrode 50 and the insulating layer 60. The first wiring line 70 is coupled to the first electrode 50 via the first contact hole 62 provided in the insulating layer 60. For the first wiring line 70, for example, a Cu layer, an Al layer, or an Au layer is used.

As illustrated in FIG. 2, the second wiring line 72 is provided on the opposite side of the insulating layer 60 from the substrate 10. The second wiring line 72 is provided on the second electrodes 52 and on the insulating layer 60. The second wiring line 72 is coupled to the second electrodes 52 via the second contact holes 64 provided in the insulating layer 60. The second wiring line 72 is electrically coupled to the first semiconductor layer 40. In the illustrated example, the second wiring line 72 is electrically coupled to the first semiconductor layer 40 via the second electrodes 52. The second wiring line 72 is provided in plurality corresponding to the plurality of light-emitting elements 102.

The second wiring line 72 includes, for example, a first layer 74 and a second layer 76. The first layer 74 is provided on the upper surface of the second electrodes 52, the side surfaces of the insulating layer 60 that define the second contact holes 64, and the upper surface of the insulating layer 60. In the example illustrated in FIG. 1, the planar shape of the first layer 74 is circular. For the first layer 74, for example, ITO or ZnO is used. The second layer 76 is provided on the upper surface of the insulating layer 60. The second layer 76 couples the first layer 74 and the pads 80. The planar shape of the second layer 76 is substantially rectangular. For the second layer 76, for example, a Cu layer, an Al layer, or an Au layer is used.

The second wiring line 72 overlaps at least one of the plurality of second column portions 30b as viewed from the stacking direction. In the illustrated example, the second layer 76 of the second wiring line 72 overlaps a plurality of second column portions 30b as viewed from the stacking direction. The second layer 76 of the second wiring line 72 overlaps the second region 26 as viewed from the stacking direction.

The pads 80 are provided on the insulating layer 60. For example, wire bondings (not illustrated) are coupled to the pads 80. The planar shape of the pads 80 is rectangular. The size in the Y-axis direction of the pads 80 is greater than the size in the Y-axis direction of the second layer 76. The pads 80 are provided in plurality corresponding to the plurality of light-emitting elements 102. The material of the pads 80 is, for example, the same as that of the second layer 76.

Note that in the above description, a case in which the u-type semiconductor layer 34 of the first column portions 30a is an InGaN system has been described. However, for the u-type semiconductor layer 34 of the first column portions 30a, various material systems capable of emitting light upon injection of current can be used in accordance with the wavelength of light to be emitted. For example, semiconductor materials such as an AlGaN system, an AlGaAs system, an InGaAs system, an InGaAsP system, an InP system, a GaP system, an AlGaP system, or the like can be used.

Furthermore, the light-emitting elements 102 are not limited to lasers, and may be light-emitting diodes (LED).

### 1.2. Method of Manufacturing Light-Emitting Device

Next, a method of manufacturing the light-emitting device 100 according to the first embodiment will be described with reference to drawings. FIGS. 5 and 6 are cross-sectional views schematically illustrating manufacturing steps for the light-emitting device 100 according to the first embodiment.

As illustrated in FIG. 5, the buffer layer 22 is epitaxially grown on the substrate 10. Examples of epitaxial growth methods include metal organic chemical vapor deposition (MOCVD) methods and molecular beam epitaxy (MBE) methods.

Next, a mask layer (not illustrated) is formed on the buffer layer 22. The mask layer is formed by, for example, film formation by an electron beam vapor deposition method, a sputtering method, or the like, and patterning. Patterning is performed, for example, by electron beam lithography and dry etching.

Next, with the mask layer serving as the mask, the n-type semiconductor layer 32, the u-type semiconductor layer 34, and the p-type semiconductor layer 36 are epitaxially grown in this order on the buffer layer 22. Examples of epitaxial growth methods include MOCVD methods and MBE methods. With this step, the plurality of column portions 30 can be formed.

As illustrated in FIG. 6, the first semiconductor layer 40 is formed on the plurality of first column portions 30a. Specifically, the first semiconductor layer 40 is epitaxially grown. Examples of methods of epitaxially growing the first semiconductor layer 40 include MOCVD methods and MBE methods. The first semiconductor layer 40 is grown under a condition that more easily causes spreading in the lateral direction than when the column portions 30 are grown.

Next, the second electrodes 52 are formed on the first semiconductor layer 40. The second electrodes 52 are formed by, for example, film formation by a sputtering method, a vacuum vapor deposition method, or the like, and patterning. Patterning is performed, for example, by photolithography and etching. This etching allows the second electrodes 52 and the first semiconductor layer 40 to be etched in a batch manner.

As illustrated in FIG. 4, the first electrode 50 is formed on the buffer layer 22. The first electrode 50 is formed by, for example, film formation by a sputtering method, a vacuum vapor deposition method, or the like, and patterning. Patterning is performed, for example, by photolithography and etching. With this step, the plurality of light-emitting elements 102 can be formed. Note that the order of the step of forming the first electrode 50 and the step of forming the second electrodes 52 is not particularly limited.

As illustrated in FIGS. 2 and 4, the insulating layer 60 covering the plurality of second column portions 30b, the first electrode 50, and the second electrodes 52 is formed. The insulating layer 60 is formed by, for example, a chemical vapor deposition (CVD) method, a spin coating method, or the like.

Next, the insulating layer 60 is patterned to form the first contact hole 62 and the second contact holes 64. Patterning is performed, for example, by photolithography and etching.

As illustrated in FIG. 2, the first layer 74 is formed on the second electrodes 52. Next, the second layer 76 and the pads 80 are formed on the insulating layer 60. The first layer 74, the second layer 76, and the pads 80 are formed by, for example, a sputtering method or a vacuum vapor deposition method. With this step, the second wiring line 72 including the first layer 74 and the second layer 76 can be formed.

As illustrated in FIG. 1, the first wiring line 70 coupled to the first electrode 50 is formed. The first wiring line 70 is formed by, for example, a sputtering method or a vacuum vapor deposition method. Note that the order of the step of forming the first wiring line 70 and the step of forming the second wiring line 72 is not particularly limited.

With the above steps, the light-emitting device 100 can be manufactured.

### 1.3. Action and Advantageous Effects

In the light-emitting device 100, the plurality of second column portions 30b surround the plurality of first column portions 30a as viewed from the stacking direction, and thus the level difference of the portion at which the insulating layer 60 is provided can be reduced. Accordingly, in the light-emitting device 100, it is possible to improve the adhesion of the insulating layer 60. This makes it possible to reduce the possibility of any of the first column portions 30a and the second wiring line 72 coming into contact with each other. As a result, it is possible to reduce the possibility of a leak current flowing between any of the first column portions 30a and the second wiring line 72. Further, it is possible to reduce the possibility of the second wiring line 72 being broken.

Further, in the light-emitting device 100, each of the plurality of first column portions 30a and each of the plurality of second column portions 30b include the n-type semiconductor layer 32, the u-type semiconductor layer 34, and the p-type semiconductor layer 36. Accordingly, in the light-emitting device 100, as compared to a case in which the second column portions do not include the p-type semiconductor layer, the difference in height between the first column portions 30a and the second column portions 30b can be reduced. This makes it possible to reduce the level difference of the portion at which the insulating layer 60 is provided.

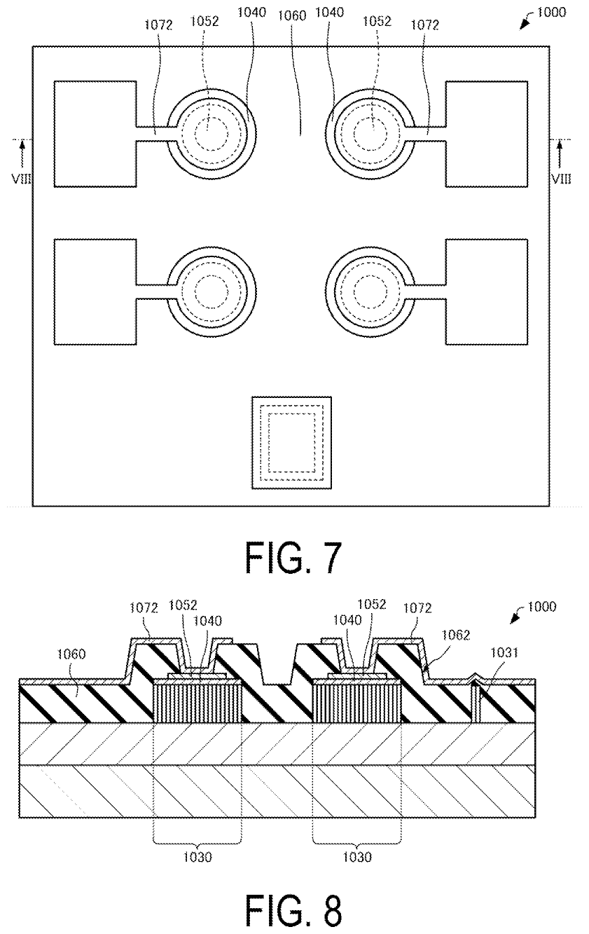

Here, FIG. 7 is a plan view schematically illustrating a light-emitting device 1000 according to a first reference example. FIG. 8 is a cross-sectional view taken along the line VIII-VIII in FIG. 7 that schematically illustrate the light-emitting device 1000 according to the first reference example.

In the method of manufacturing the light-emitting device 1000, after a plurality of column portions 1030 are grown, column portions 1030 other than a plurality of column portions 1030 coupled to a first semiconductor layer 1040 are etched. Accordingly, a level difference is formed between the region in which a plurality of column portions 1030 are provided and the region in which no column portion 1030 is provided. To reflect this level difference, a level difference is also formed in an insulating layer 1060. Stepped portions 1062 of the insulating layer 1060 tend to be thinner than the other portions, and are susceptible to damage such as cracks due to stress. Accordingly, a leak current easily flows between the second wiring line 1072 coupled to second electrodes 1052 and any of the column portions 1030.

Further, in the method of manufacturing the light-emitting device 1000, an etching residue 1031 may occur when etching column portions 1030. When an etching residue 1031 occurs, there is a possibility of a leak current flowing between the second wiring line 1072 and the etching residue 1031, causing light to be emitted at an unintended location.

As described above, the light-emitting device 100 includes a plurality of second column portions 30b that surround a plurality of first column portions 30a as viewed from the stacking direction and that do not emit light, and thus the problems as described above can be solved.

The light-emitting device 100 includes the second electrodes 52 provided on the opposite side of the first semiconductor layer 40 from the substrate 10, with the second wiring line 72 being coupled to the second electrodes 52 via the second contact holes 64 provided in the insulating layer 60. Accordingly, in the light-emitting device 100, it is possible to inhibit the electrode material from entering between adjacent first column portions as compared to a case in which the second electrodes are directly provided at a plurality of first column portions. Further, the flatness of the second electrodes 52 can be enhanced.

In the light-emitting device 100, the second electrodes 52 completely overlap the first semiconductor layer 40 as viewed from the stacking direction. Accordingly, in the light-emitting device 100, etching of the first semiconductor layer 40 and etching of the second electrodes 52 can be performed in the same step in a batch manner. This makes it possible to shorten the manufacturing steps. Note that etching of the first semiconductor layer 40 and etching of the second electrodes 52 may be performed in separate steps.

### 2. Second Embodiment

### 2.1. Light-Emitting Device

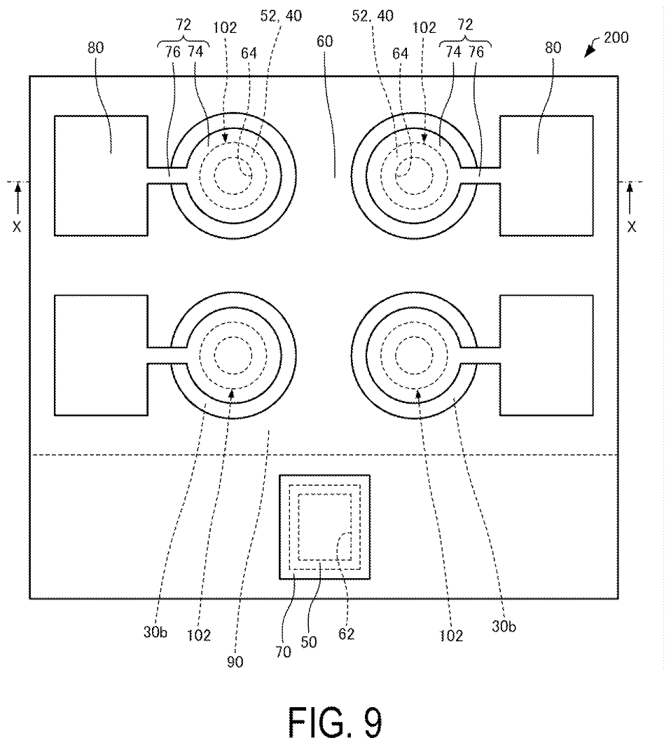

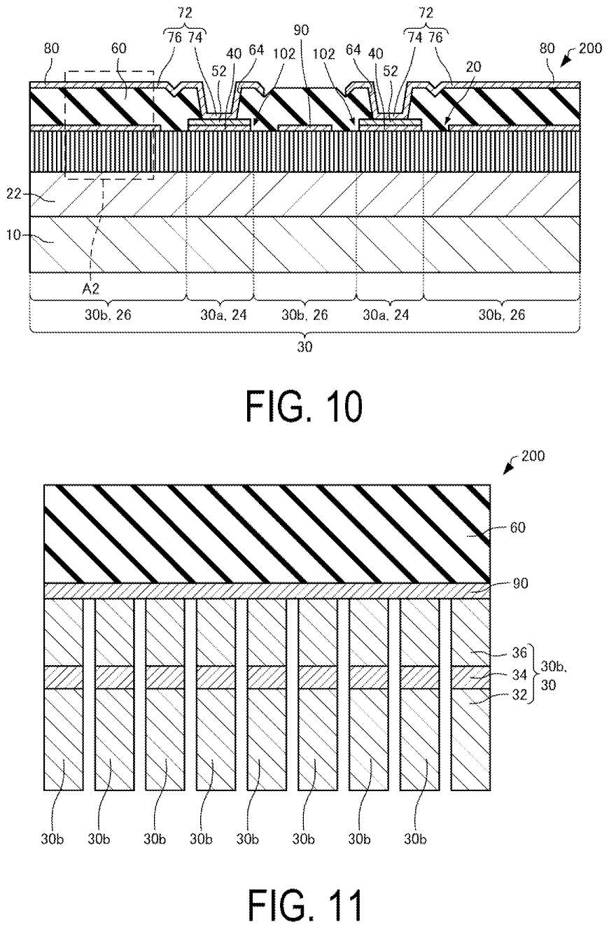

Next, a light-emitting device according to a second embodiment will be described with reference to drawings. FIG. 9 is a plan view schematically illustrating a light-emitting device 200 according to the second embodiment. FIG. 10 is a cross-sectional view taken along the line X-X in FIG. 9 that schematically illustrate the light-emitting device 200 according to the second embodiment. FIG. 11 is a cross-sectional view schematically illustrating the light-emitting device 200 according to the second embodiment, and is an enlarged view of the region A2 in FIG. 10. Note that in FIG. 10, column portions 30 are illustrated in a simplified manner for convenience. Furthermore, in FIG. 11, members other than the column portions 30, the insulating layer 60, and a fifth semiconductor layer 90 are omitted from illustration.

Hereinafter, in the light-emitting device 200 according to the second embodiment, members having a function similar to that of the corresponding components of the light-emitting device 100 according to the first embodiment described above are denoted by the identical reference signs, with detailed description thereof being omitted. The same applies to the light-emitting device according to a third embodiment to be described later.

As illustrated in FIGS. 9 to 11, the light-emitting device 200 differs from the light-emitting device 100 described above in that the fifth semiconductor layer 90 is provided.

As illustrated in FIGS. 10 and 11, the fifth semiconductor layer 90 is provided on the opposite side of the plurality of second column portions 30b from the substrate 10. The fifth semiconductor layer 90 is provided on the plurality of second column portions 30b. The fifth semiconductor layer 90 is provided between the plurality of second column portions 30b and the insulating layer 60. The fifth semiconductor layer 90 is coupled to the plurality of second column portions 30b.

The fifth semiconductor layer 90 is electrically separated from the first semiconductor layer 40. In the illustrated example, the fifth semiconductor layer 90 is spaced apart from the first semiconductor layer 40. The fifth semiconductor layer 90 surrounds the first semiconductor layer 40 as viewed from the stacking direction. The fifth semiconductor layer 90 is electrically separated from the second electrodes 52. The thickness of the fifth semiconductor layer 90 is, for example, the same as the thickness of the first semiconductor layer 40. The material of the fifth semiconductor layer 90 is, for example, the same as that of the first semiconductor layer 40.

### 2.2. Method of Manufacturing Light-Emitting Device

Next, a method of manufacturing the light-emitting device 200 according to the second embodiment will be described with reference to drawings. As illustrated in FIG. 10, the method of manufacturing the light-emitting device 200 is basically the same as the method of manufacturing the light-emitting device 100 described above except that the first semiconductor layer 40 and the fifth semiconductor layer 90 are formed in the same step. Therefore, detailed description thereof is omitted.

### 2.3. Action and Advantageous Effects

The light-emitting device 200 includes the fifth semiconductor layer 90 that is provided on the opposite side of the plurality of second column portions 30b from the substrate 10 and that is coupled to the plurality of second column portions 30b, and the fifth semiconductor layer 90 is electrically separated from the first semiconductor layer 40. Accordingly, in the light-emitting device 200, the flatness of the upper surface of the insulating layer 60 can be enhanced. This makes it possible to further reduce the possibility of the second wiring line 72 being broken.

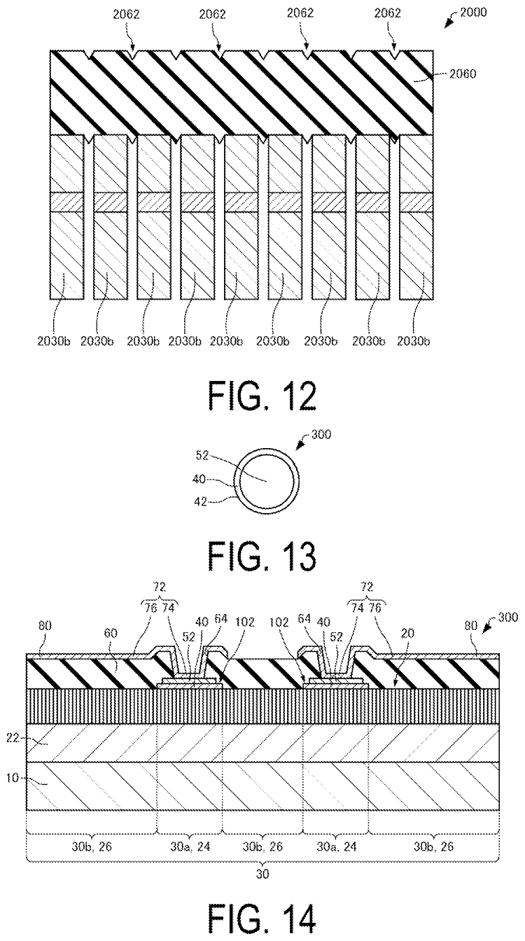

For example, as illustrated in FIG. 12, when the insulating layer 2060 enters between adjacent second column portions 2030b, a recess 2062 may be formed in the upper surface of the insulating layer 2060. Accordingly, the flatness of the upper surface of the insulating layer 2060 may decrease. Note that FIG. 12 is a cross-sectional view schematically illustrating a light-emitting device 2000 according to a second reference example.

In the light-emitting device 200, the thickness of the fifth semiconductor layer 90 is the same as the thickness of the first semiconductor layer 40. Accordingly, in the light-emitting device 200, for example, the first semiconductor layer 40 and the fifth semiconductor layer 90 can be formed in the same step. This makes it possible to shorten the manufacturing steps.

### 3. Third Embodiment

### 3.1. Light-Emitting Device

Next, a light-emitting device according to a third embodiment will be described with reference to drawings. FIG. 13 is a plan view schematically illustrating a light-emitting device 300 according to the third embodiment. FIG. 14 is a cross-sectional view schematically illustrating the light-emitting device 300 according to the third embodiment. Note that in FIG. 13, members other than the first semiconductor layer 40 and a second electrode 52 are omitted from illustration for convenience. Furthermore, in FIG. 14, the column portions 30 are illustrated in a simplified manner.

In the light-emitting device 100 described above, as illustrated in FIGS. 1 and 2, the second electrodes 52 completely overlap the first semiconductor layer 40 as viewed from the stacking direction.

In contrast, in the light-emitting device 300, as illustrated in FIGS. 13 and 14, the second electrode 52 is provided on the inner side of the outer edge 42 of the first semiconductor layer 40 as viewed from the stacking direction. The second electrode 52 does not overlap the outer edge 42.

### 3.2. Method of Manufacturing Light-Emitting Device

Next, a method of manufacturing the light-emitting device 300 according to the third embodiment will be described. The method of manufacturing the light-emitting device 300 is basically the same as the method of manufacturing the light-emitting device 100 described above. Therefore, detailed description thereof is omitted.

### 3.3. Action and Advantageous Effects

In the light-emitting device 300, as viewed from the stacking direction, the second electrode 52 is provided on the inner side of the outer edge 42 of the first semiconductor layer 40, and does not overlap the outer edge 42. Accordingly, in the light-emitting device 300, it is possible to secure sufficient accuracy in the manufacturing steps as compared to a case in which the second electrode is formed so as to completely overlap the first semiconductor layer as viewed from the stacking direction, for example.

### 4. Fourth Embodiment

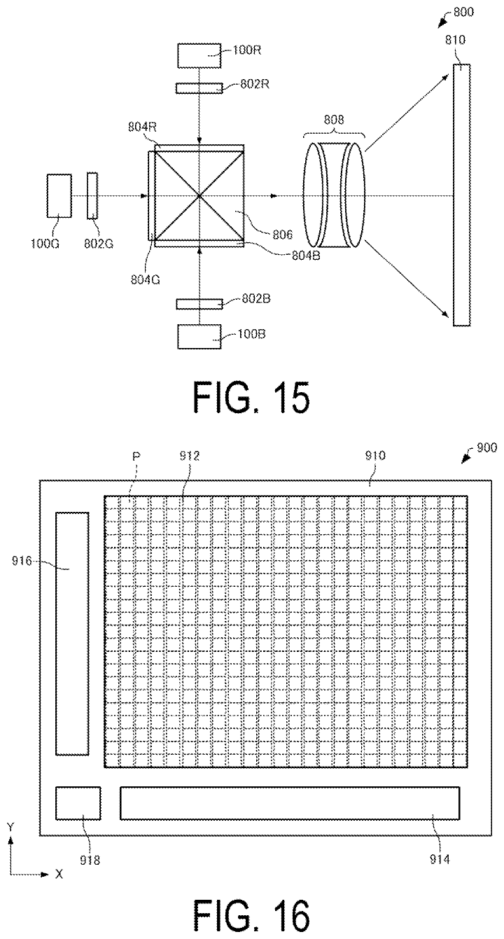

Next, a projector according to a fourth embodiment will be described with reference to drawings. FIG. 15 is a view schematically illustrating a projector 800 according to the fourth embodiment.

The projector 800 includes, for example, light-emitting devices 100 as light source.

The projector 800 includes a housing (not illustrated), and a red light source 100R, a green light source 100G, and a blue light source 100B that are included in the housing and that emit red light, green light, and blue light, respectively. Note that in FIG. 15, the red light source 100R, the green light source 100G, and the blue light source 100B are simplified for convenience.

The projector 800 further includes a first optical element 802R, a second optical element 802G, a third optical element 802B, a first optical modulation device 804R, a second optical modulation device 804G, a third optical modulation device 804B, and a projection device 808, which are included in the housing. The first optical modulation device 804R, the second optical modulation device 804G, and the third optical modulation device 804B are each, for example, a transmission-type liquid crystal light valve. The projection device 808 is, for example, a projection lens.

Light emitted from the red light source 100R is incident on the first optical element 802R. Light emitted from the red light source 100R is focused by the first optical element 802R. Note that the first optical element 802R may have a function other than that of focusing. The same applies to the second optical element 802G and the third optical element 802B to be described later.

Light focused by first optical element 802R is incident on the first optical modulation device 804R. The first optical modulation device 804R modulates incident light in accordance with image information. Then, the projection device 808 enlarges and projects the image formed by the first optical modulation device 804R onto a screen 810.

The light emitted from the green light source 100G is incident on the second optical element 802G. The light emitted from the green light source 100G is focused by the second optical element 802G.

The light focused by the second optical element 802G is incident on the second optical modulation device 804G. The second optical modulation device 804G modulates incident light in accordance with image information. Then, the projection device 808 enlarges and projects the image formed by the second optical modulation device 804G onto the screen 810.

Light emitted from the blue light source 100B is incident on the third optical element 802B. Light emitted from the blue light source 100B is focused by the third optical element 802B.

Light focused by the third optical element 802B is incident on the third optical modulation device 804B. The third optical modulation device 804B modulates incident light in accordance with image information. Then, the projection device 808 enlarges and projects the image formed by the third optical modulation device 804B onto the screen 810.

The projector 800 can also include a cross dichroic prism 806 that synthesizes and guides light emitted from the first optical modulation device 804R, the second optical modulation device 804G, and the third optical modulation device 804B to the projection device 808.

Light of three colors modulated by the first optical modulation device 804R, the second optical modulation device 804G, and the third optical modulation device 804B, respectively, is incident on the cross dichroic prism 806. The cross dichroic prism 806 is formed by bonding together four right-angle prisms. A dielectric multilayer film that reflects red light and a dielectric multilayer film that reflects blue light are disposed on an inner surface of the cross dichroic prism 806. The light of three colors is synthesized by these dielectric multilayer films to form light representing a color image. Then, the synthesized light is projected onto the screen 810 by the projection device 808, causing an enlarged image to be displayed.

Note that by controlling light-emitting devices 100 as image pixels in accordance with image information, the red light source 100R, the green light source 100G, and the blue light source 100B may directly form an image without using the first optical modulation device 804R, the second optical modulation device 804G, and the third optical modulation device 804B. Then, the projection device 808 may enlarge and project the image formed by the red light source 100R, the green light source 100G, and the blue light source 100B onto the screen 810.

Furthermore, in the example described above, transmission-type liquid crystal light valves are used as optical modulation devices; however, light valves other than liquid crystal light valves may be used, and reflective light valves may be used. Examples of such light valves include reflective liquid crystal light valves and digital micromirror devices. Furthermore, the configuration of the projection device is modified as appropriate depending on the type of light valves used.

The light source can also be applied to a light source device of a scanning type image display device, such as one including a scanning means that is an image forming device and that causes light from a light source to scan a screen and thereby causes an image of a desired size to be displayed on a display surface.

### 5. Fifth Embodiment

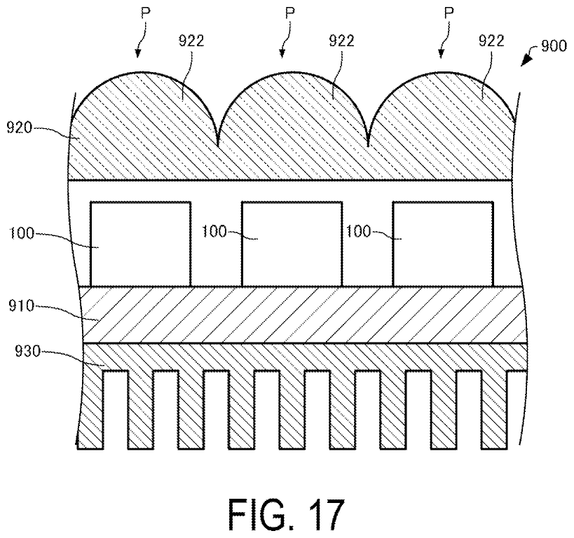

Next, a display according to a fifth embodiment will be described with reference to drawings. FIG. 16 is a plan view schematically illustrating a display 900 according to the fifth embodiment. FIG. 17 is a cross-sectional view schematically illustrating the display 900 according to the fifth embodiment. Note that in FIG. 16, the X-axis and the Y-axis are illustrated as two axes orthogonal to each other for convenience.

The display 900 includes, for example, light-emitting devices 100 as light source.

The display 900 is a display device that displays an image. The image includes those that only display character information. The display 900 is a self-luminous display. As illustrated in FIGS. 16 and 17, the display 900 includes a printed wired board 910, a lens array 920, and a heat sink 930.

The printed wired board 910 is equipped with a driving circuit for driving the light-emitting devices 100. The driving circuit is, for example, a circuit including a complementary metal oxide semiconductor (CMOS) or the like. The driving circuit drives the light-emitting devices 100 based on input image information, for example. Although not illustrated, a light-transmitting substrate for protecting the printed wired board 910 is disposed on the printed wired board 910.

The printed wired board 910 includes a display region 912, a data line driving circuit 914, a scanning line driving circuit 916, and a control circuit 918.

The display region 912 is constituted by a plurality of pixels P. In the illustrated example, the pixels P are arranged along the X-axis and the Y-axis.

Although not illustrated, a plurality of scanning lines and a plurality of data lines are provided in the printed wired board 910. For example, the scanning lines extend along the X-axis, and the data lines extend along the Y-axis. The scanning lines are coupled to the scanning line driving circuit 916. The data lines are coupled to the data line driving circuit 914. The pixels P are provided corresponding to intersections between the scanning lines and the data lines.

One pixel P includes, for example, one light-emitting device 100, one lens 922, and a pixel circuit (not illustrated). The pixel circuit includes a switching transistor that functions as a switch of the pixel P. The gate of the switching transistor is coupled to the scanning line, and one of the source/drain is coupled to the data line.

The data line driving circuit 914 and the scanning line driving circuit 916 are circuits that control the driving of the light-emitting devices 100 that constitute the pixels P. The control circuit 918 controls the displaying of an image.

Image data is supplied from an upper circuit to the control circuit 918. The control circuit 918 supplies various signals based on such image data to the data line driving circuit 914 and scanning line driving circuit 916.

When the scanning line driving circuit 916 activates a scanning signal to select a scanning line, a switching transistor of the selected pixel P is turned on. At this time, the data line driving circuit 914 supplies a data signal from a data line to the selected pixel P, causing the light-emitting device 100 of the selected pixel P to emit light in accordance with the data signal.

The lens array 920 includes a plurality of lenses 922. For example, one lens 922 is provided for one light-emitting device 100. Light emitted from the light-emitting device 100 is incident on one lens 922.

The heat sink 930 is in contact with the printed wired board 910. The material of the heat sink 930 is, for example, a metal such as copper and aluminum. The heat sink 930 dissipates heat generated at the light-emitting devices 100.

The light-emitting device according to the embodiments described above can be used in applications other than projectors and displays. Applications other than projectors and displays include indoor and outdoor lighting, laser printers, scanners, on-vehicle lights, sensing apparatuses that use light, and light sources for communication apparatuses. The light-emitting device according to the embodiments described above can also be used as display devices for head-mounted displays.

The embodiments and modified examples described above are examples, and the present disclosure is not limited thereto. For example, any of the embodiments and the modified examples can be combined as appropriate.

The present disclosure encompasses configurations that are substantially identical to the configurations described in the embodiments: for example, configurations that have a function, method, and result identical to those of the configurations described in the embodiments, or configurations that have an object and advantageous effect identical to those of the configurations described in the embodiments. The present disclosure also encompasses configurations obtained by replacing a non-essential portion of the configurations described in the embodiments. The present disclosure also encompasses configurations that achieve an action and advantageous effect identical to those of the configurations described in the embodiments, or configurations that can achieve an object identical to that of the configurations described in the embodiments. The present disclosure also encompasses configurations obtained by adding a known technology to the configurations described in the embodiments.

The following contents are derived from the embodiments and modified examples described above.

One aspect of a light-emitting device includes: a substrate; a plurality of first column portions provided at the substrate; a plurality of second column portions that is provided at the substrate and that surround the plurality of first column portions as viewed from a normal direction of the substrate; a first semiconductor layer that is provided on an opposite side of the plurality of first column portions from the substrate and that is coupled to the plurality of first column portions; an insulating layer covering the first semiconductor layer and the plurality of second column portions; and a wiring line that is provided on an opposite side of the insulating layer from the substrate and that is electrically coupled to the first semiconductor layer; wherein each of the plurality of first column portions and each of the plurality of second column portions includes an n-type second semiconductor layer, a p-type third semiconductor layer, and a u-type fourth semiconductor layer provided between the second semiconductor layer and the third semiconductor layer, the fourth semiconductor layer at each of the plurality of first column portions is injected with current to emit light, the fourth semiconductor layer at each of the plurality of second column portions is not injected with current, and the wiring line overlaps at least one of the plurality of second column portions as viewed from the normal direction.

According to this light-emitting device, it is possible to reduce the possibility of a leak current flowing between any of the first column portions and the wiring line.

One aspect of the light-emitting device includes: a fifth semiconductor layer that is provided on an opposite side of the plurality of second column portions from the substrate and that is coupled to the plurality of second column portions; wherein the fifth semiconductor layer may be electrically separated from the first semiconductor layer.

According to this light-emitting device, the flatness of the upper surface of the insulating layer can be enhanced.

In one aspect of the light-emitting device, a thickness of the fifth semiconductor layer is the same as a thickness of the first semiconductor layer and material of the fifth semiconductor layer may be the same as material of the first semiconductor layer.

According to this light-emitting device, for example, the first semiconductor layer and the fifth semiconductor layer can be formed in the same step.

One aspect of the light-emitting device includes: an electrode provided on an opposite side of the first semiconductor layer from the substrate; wherein the wiring line may be coupled to the electrode via a contact hole provided at the insulating layer.

According to this light-emitting device, it is possible to inhibit the electrode material from entering between adjacent first column portions.

In one aspect of the light-emitting device, the electrode may completely overlap the first semiconductor layer as viewed from the normal direction.

According to this light-emitting device, etching of the first semiconductor layer and etching of the electrode can be performed in the same step in a batch manner.

In one aspect of the light-emitting device, as viewed from the normal direction, the electrode is provided on an inner side of an outer edge of the first semiconductor layer and need not overlap the outer edge.

According to this light-emitting device, it is possible to secure a wide accuracy margin in the manufacturing steps.

One aspect of a projector includes one aspect of the light-emitting device.

One aspect of a display includes one aspect of the light-emitting device.

What is claimed is:

1. A light-emitting device comprising:
a substrate;
a plurality of first column portions provided at the substrate;
a plurality of second column portions provided at the substrate and surrounding the plurality of first column portions when viewed from a normal direction of the substrate;
a first semiconductor layer provided on an opposite side of the plurality of first column portions from the substrate, and coupled to the plurality of first column portions;
an insulating layer covering the first semiconductor layer and the plurality of second column portions; and
a wiring line provided on an opposite side of the insulating layer from the substrate, and electrically coupled to the first semiconductor layer, wherein
each of the plurality of first column portions and each of the plurality of second column portions include
an n-type second semiconductor layer,
a p-type third semiconductor layer, and
a u-type fourth semiconductor layer provided between the second semiconductor layer and the third semiconductor layer,
the fourth semiconductor layer included in each of the plurality of first column portions is injected with current to emit light,
the fourth semiconductor layer included in each of the plurality of second column portions is not injected with current, and
the wiring line overlaps at least one of the plurality of second column portions when viewed from the normal direction.

2. The light-emitting device according to claim 1, comprising
a fifth semiconductor layer provided on an opposite side of the plurality of second column portions from the substrate, and coupled to the plurality of second column portions, wherein
the fifth semiconductor layer is electrically isolated from the first semiconductor layer.

3. The light-emitting device according to claim 2, wherein
a thickness of the fifth semiconductor layer is same as a thickness of the first semiconductor layer, and
material of the fifth semiconductor layer is same as material of the first semiconductor layer.

4. The light-emitting device according to claim 1, comprising
an electrode provided on an opposite side of the first semiconductor layer from the substrate, wherein
the wiring line is coupled to the electrode through a contact hole provided at the insulating layer.

5. The light-emitting device according to claim 4, wherein
the electrode completely overlaps the first semiconductor layer when viewed from the normal direction.

6. The light-emitting device according to claim 4, wherein
the electrode is provided inside an outer edge of the first semiconductor layer and does not overlap the outer edge when viewed from the normal direction.

7. A projector comprising the light-emitting device according to claim 1.

8. A display comprising the light-emitting device according to claim 1.
